(19) United States
(12) Patent Application Publication
(10) Pub. No.: US 2011/0177454 A1
(43) Pub. Date: Jul. 21, 2011

(54) RESIST MATERIAL AND PATTERN FORMATION METHOD USING THE RESIST MATERIAL

(75) Inventors: Masayuki Endou, Osaka (JP); Masaru Sasago, Osaka (JP)

(73) Assignee: PANASONIC CORPORATION, Osaka (JP)

(21) Appl. No.: 13/079,423

(22) Filed: Apr. 4, 2011

Related U.S. Application Data
(63) Continuation of application No. PCT/JP2009/004214, filed on Aug. 28, 2009.

(30) Foreign Application Priority Data
Dec. 16, 2008 (JP) 2008-319623

(51) Int. Cl. G03F 7/004; G03F 7/20

(52) U.S. Cl. 430/281.1; 430/270.1; 430/325; 430/296

(57) ABSTRACT

First, a resist film is formed on a substrate from a resist material including cyclic oligomer which does not contain any acid-labile group, is soluble in alkali, and is a trimer or a higher multimer; a molecular compound containing an acid-labile group; a photoacid generator; and no polymer. Then, pattern exposure is performed by selectively irradiating the formed resist film with exposure light of extreme ultraviolet. The resist film after the pattern exposure is heated, and then, the heated resist film is developed to form a resist pattern from the resist film.

### CROSS-REFERENCE TO RELATED APPLICATION

This is a continuation of PCT International Application PCT/JP2009/004214 filed on Aug. 28, 2009, which claims priority to Japanese Patent Application No. 2008-319623 filed on Dec. 16, 2008. The disclosures of these applications including the specifications, the drawings, and the claims are hereby incorporated by reference in their entirety.

### BACKGROUND

The present disclosure relates to resist materials used in manufacturing processes etc. of semiconductor devices and pattern formation methods using the resist materials.

With increasing integration of semiconductor integrated circuits and downsizing of semiconductor elements, accelerated development of lithography techniques has been demanded. At present, pattern formation is performed by optical lithography using mercury lamps, KrF excimer laser, ArF excimer laser, or the like as exposure light. Use of extreme ultraviolet with a shorter wavelength is also considered. Extreme ultraviolet has a reduced wavelength of 13.5 nm, which is one-tenth or less of that in conventional optical lithography, and thus, a significant improvement in resolution can be expected.

In exposure with extreme ultraviolet, since the density of patterns increases, and it is important to reduce roughness of patterns. In order to address the problem, molecular resist is suggested (see, e.g., Japanese Patent Publication No. 2008-89871). Since solubility of molecular resist is equalized in development, a decrease in roughness of patterns is expected.

A pattern formation method by conventional lithography using molecular resist for a resist film will be described below with reference to FIGS. 5A-5D.

First, a chemically amplified molecular resist material having the following composition is prepared.

1,1,1-Tri(t-butyloxycarbonyl-phenyl)ethane (molecular compound containing an acid-labile group): 2 g

Triphenylsulfonium trifluoromethanesulfonate (photoacid generator): 0.05 g

Triethanolamine (quencher): 0.002 g

Propylene glycol monomethyl ether acetate (solvent): 20 g

Next, as shown in FIG. 5 A, the molecular resist material is applied onto a substrate 1. Then, a resist film 2 applied with the material is heated at the temperature of 90° C. for 60 seconds, thereby forming the resist film 2 with a thickness of 50 nm.

After that, as shown in FIG. 5B, pattern exposure is performed by irradiating the resist film 2 with exposure light of extreme ultraviolet having a numerical aperture (NA) of 0.25 and a wavelength of 13.5 nm via a mask.

Then, as shown in FIG. 5C, the resist film 2 after the pattern exposure is heated with a hot plate at the temperature of 105° C. for 60 seconds.

Next, the heated resist film 2 is developed with a tetramethylammonium hydroxide developer at a concentration of 2.38 wt %, thereby obtaining, as shown in FIG. 5D, a resist pattern 2a formed of an unexposed portion of the resist film 2 and having a line width of 50 nm.

### SUMMARY

However, as shown in FIG. 5D, in the resist pattern 2a obtained by the conventional pattern formation method, patterns are deformed at the time of heating after the exposure, resulting in difficulty in pattern formation with excellent forms.

As such, when a film to be processed is etched using the deformed resist pattern 2a, a pattern obtained from the film to be processed is also deformed. This reduces productivity and the yield in a manufacturing process of a semiconductor device.

In view of the problems, it is an objective of the present disclosure to reduce deformation of resist patterns using a molecular resist material.

After repeated studies of pattern deformation with conventional molecular resist materials, the present inventors reached the following conclusion. Specifically, since molecules of a molecular resist material contain an acid-labile group, the glass transition temperature of the obtained resist film drops to cause pattern deformation at the time of heating after exposure.

Then, the present inventors repeated various further studies, and found that pattern forms are improved when combining cyclic oligomer which does not contain any acid-labile group, is soluble in alkali, and is a trimer or a higher multimer, and a molecular compound containing an acid-labile group.

More specifically, in cyclic oligomer which does not contain any acid-labile group, is soluble in alkali, and is a trimer or a higher multimer, the glass transition temperature is less reduced, and a molecular compound containing an acid-labile group is diffused in a resist film. This increases solution blockage of a developer of alkali-soluble cyclic oligomer in an unexposed portion to improve development contrast.

When the oligomer not containing the acid-labile group, and being the trimer or the higher multimer has a non-cyclic structure, the glass transition temperature is largely reduced. This may be because the molecule structure is not stiff. Even when the monomer itself of oligomer includes a cyclic structure, the glass transition temperature is largely reduced as long as the oligomer does not have the cyclic structure as a whole. Therefore, regardless of whether or not the monomer includes a cyclic structure, it is important to have a cyclic structure as oligomer. In general, oligomer is polymer with relatively low molecular weight up to about 100 monomers.

Specifically, a resist material according to the present disclosure includes cyclic oligomer which does not contain any acid-labile group, is soluble in alkali, and is a trimer or a higher multimer; a molecular compound containing an acid-labile group; a photoacid generator; and no polymer.

In the resist material according to the present disclosure, in the cyclic oligomer which does not contain any acid-labile group, is soluble in alkali, and is a trimer or a higher multimer, the glass transition temperature is less reduced, and the molecular compound containing an acid-labile group is diffused in the resist film. This increases solution blockage of a developer of alkali-soluble cyclic oligomer in an unexposed portion to improve development contrast. Since the resist film does not contain polymer, a pattern with reduced roughness and an excellent form can be formed. If polymer is added to a resist material, uniformity in development is reduced to increase the roughness of the resist pattern. Therefore, the resist material of the present disclosure does not contain polymer. In general, polymer contains hundreds or more monomers.

In the resist material of the present disclosure, the cyclic oligomer may be cyclodextrin, calixarene, resorcinarene, pyrogallolarene, calixpyrrole, thiocalixarene, or homooxacalixarene.

In this case, the cyclodextrin may be α-cyclodextrin, β-cyclodextrin, or γ-cyclodextrin.

Also, in this case, the calixarene may be calix[4]arene, calix[6]arene, or calix[8]arene.

In the resist material of the present disclosure, the molecular compound containing an acid-labile group may be a non-cyclic molecular compound.

As such, when the molecular compound containing an acid-labile group is a non-cyclic molecular compound, less steric hindrance occurs, and thus, the compound is sufficiently diffused in the resist film to improve development contrast.

In this case, the acid-labile group in the non-cyclic molecular compound may be a t-butyl group, a t-butyloxycarbonyl group, a 1-ethoxyethyl group, a methoxymethyl group, a 2-methyladamantyl group, or a 2-ethyladamantyl group.

For example, the non-cyclic molecular compound containing an acid-labile group may be t-butyl acrylic acid, t-butyl methacrylic acid, t-butyl-α-fluoroacrylic acid, t-butyloxycarbonyl acrylic acid, t-butyloxycarbonyl methacrylic acid, t-butyloxycarbonyl-α-fluoroacrylic acid, methoxymethyl acrylic acid, methoxymethyl methacrylic acid, or methoxymethyl-α-fluoroacrylic acid.

The molecular compound containing an acid-labile group other than the above-described ones may be di(t-butyl)bisphenol A, t-butylphenol, t-butyl-o-cresol, t-butyl-m-cresol, t-butyl-p-cresol, t-butyl-1-naphthol, t-butyl-2-naphthol, di(t-butyl)catechol, di(t-butyl)resorcinol, tri(t-butyl)pyrogallol, hexa(t-butyl)hexahydroxybenzene, di(t-butyloxycarbonyl)bisphenol A, t-butyloxycarbonylphenol, t-butyloxycarbonyl-o-cresol, t-butyloxycarbonyl-m-cresol, t-butyloxycarbonyl-p-cresol, t-butyloxycarbonyl-1-naphthol, t-butyloxycarbonyl-2-naphthol, di(t-butyloxycarbonyl)catechol, di(t-butyloxycarbonyl)resorcinol, tri(t-butyloxycarbonyl)pyrogallol, hexa(t-butyloxycarbonyl)hexahydroxybenzene, di(1-ethoxyethyl)bisphenol A, 1-ethoxyethyl phenol, (1-ethoxyethyl)o-cresol, (1-ethoxyethyl)m-cresol, (1-ethoxyethyl)p-cresol, (1-ethoxyethyl)1-naphthol, (1-ethoxyethyl)2-naphthol, di(1-ethoxyethyl)catechol, di(1-ethoxyethyl)resorcinol, tri(1-ethoxyethyl)pyrogallol, hexa(1-ethoxyethyl)hexahydroxybenzene, di(methoxymethyl)bisphenol A, methoxymethylphenol, methoxymethyl-o-cresol, methoxymethyl-m-cresol, methoxymethyl-p-cresol, methoxymethyl-1-naphthol, methoxymethyl-2-naphthol, di(methoxymethyl)catechol, di(methoxymethyl)resorcinol, tri(methoxymethyl)pyrogallol, hexa(methoxymethyl)hexahydroxybenzene, 2-methylcyclopentyl acrylic acid, 2-methylcyclopentyl methacrylic acid, 2-methylcyclopentyl-α-fluoroacrylic acid, di(2-methylcyclopentyl)bisphenol A, 2-ethylcyclopentyl acrylic acid, 2-ethylcyclopentyl methacrylic acid, 2-ethylcyclopentyl-α-fluoroacrylic acid, di(2-ethylcyclopentyl)bisphenol A, 2-methyladamantyl acrylic acid, 2-methyladamantyl methacrylic acid, 2-methyladamantyl-α-fluoroacrylic acid, di(2-methyladamantyl)bisphenol A, 2-ethyladamantyl acrylic acid, 2-ethyladamantyl methacrylic acid, 2-ethyladamantyl-α-fluoroacrylic acid, or di(2-ethyladamantyl)bisphenol A.

In the resist material of the present disclosure, the photoacid generator may be triphenylsulfonium trifluoromethanesulfonate, triphenylsulfonium nonafluorobutane sulfonate, diphenyliodonium trifluoromethanesulfonate, or diphenyliodonium nonafluorobutane sulfonate.

Note that, in the present disclosure, the percentage of the molecular compound containing an acid-labile group in the cyclic oligomer which does not contain any acid-labile group, is soluble in alkali, and is a trimer or a higher multimer preferably ranges from 10 wt % to 50 wt %. This is because a slight addition of a molecular compound containing an acid-labile group may lead to an increase in solubility of an alkali developer in an unexposed portion of the resist film. Excessive addition may reduce solubility in the exposed portion of the resist film. Clearly, the present disclosure is not limited thereto. More preferably, the percentage ranges from 20 wt % to 40 wt %.

A pattern formation method according to the present disclosure includes forming on a substrate, a resist film from a resist material including cyclic oligomer which does not contain any acid-labile group, is soluble in alkali, and is a trimer or a higher multimer, a molecular compound containing an acid-labile group, a photoacid generator, and no polymer; performing pattern exposure by selectively irradiating the resist film with exposure light; heating the resist film after the pattern exposure; developing the heated resist film to form a resist pattern from the resist film.

According to the pattern formation method of the present disclosure, the resist material includes cyclic oligomer which does not contain any acid-labile group, is soluble in alkali, and is a trimer or a higher multimer; and a molecular compound containing an acid-labile group. In the cyclic oligomer which does not contain any acid-labile group, is soluble in alkali, and is a trimer or a higher multimer of the formed resist film, the glass transition temperature is less reduced. Also, the molecular compound containing an acid-labile group in the resist film is diffused in the resist film. This increases solution blockage of the developer of the alkali-soluble cyclic oligomer in an unexposed portion to improve development contrast. Since the resist material does not contain polymer, a pattern with reduced roughness and an excellent form can be formed.

In the pattern formation method of the present disclosure, the exposure light may be ArF excimer laser light, extreme ultraviolet, or an electron beam.

According to the resist material and the pattern formation method using the resist material of the present disclosure, deformation of a fine pattern with high thermal stability and high development contrast can be reduced.

### BRIEF DESCRIPTION OF THE DRAWINGS

FIGS. 1A-1D are cross-sectional views illustrating steps of a pattern formation method using a resist material according to a first embodiment of the present disclosure.

FIGS. 2A-2D are cross-sectional views illustrating steps of a pattern formation method using a resist material according to a second embodiment of the present disclosure.

FIGS. 3A-3D are cross-sectional views illustrating steps of a pattern formation method using a resist material according to a third embodiment of the present disclosure.

FIGS. 4A-4D are cross-sectional views illustrating steps of a pattern formation method using a resist material according to a fourth embodiment of the present disclosure.

FIGS. 5A-5D are cross-sectional views illustrating steps of a pattern formation method using a conventional molecular resist.

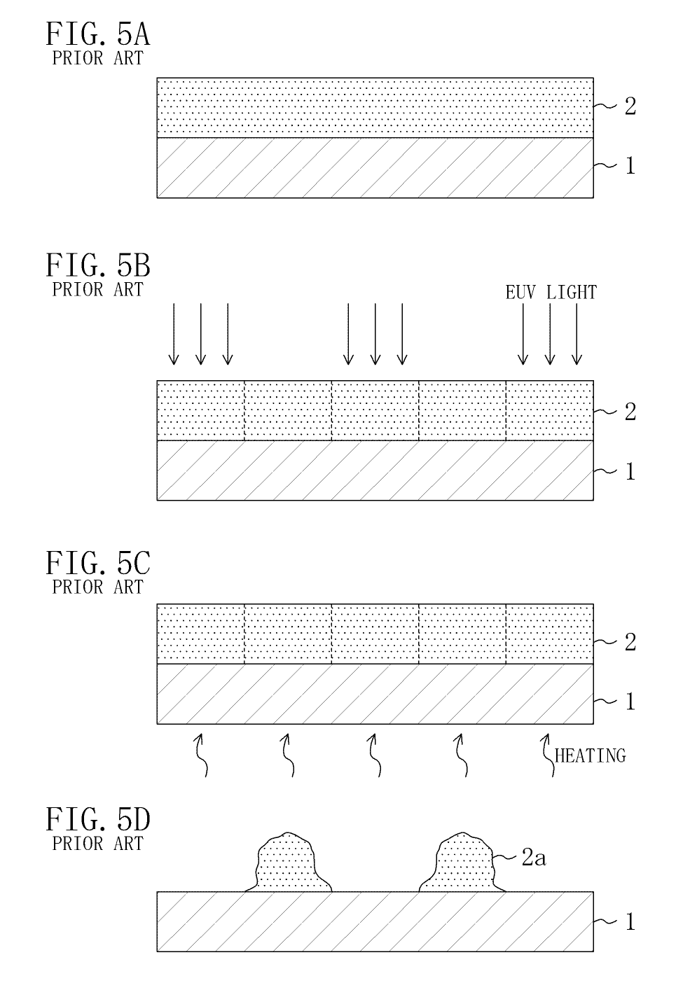

### DETAILED DESCRIPTION

### First Embodiment

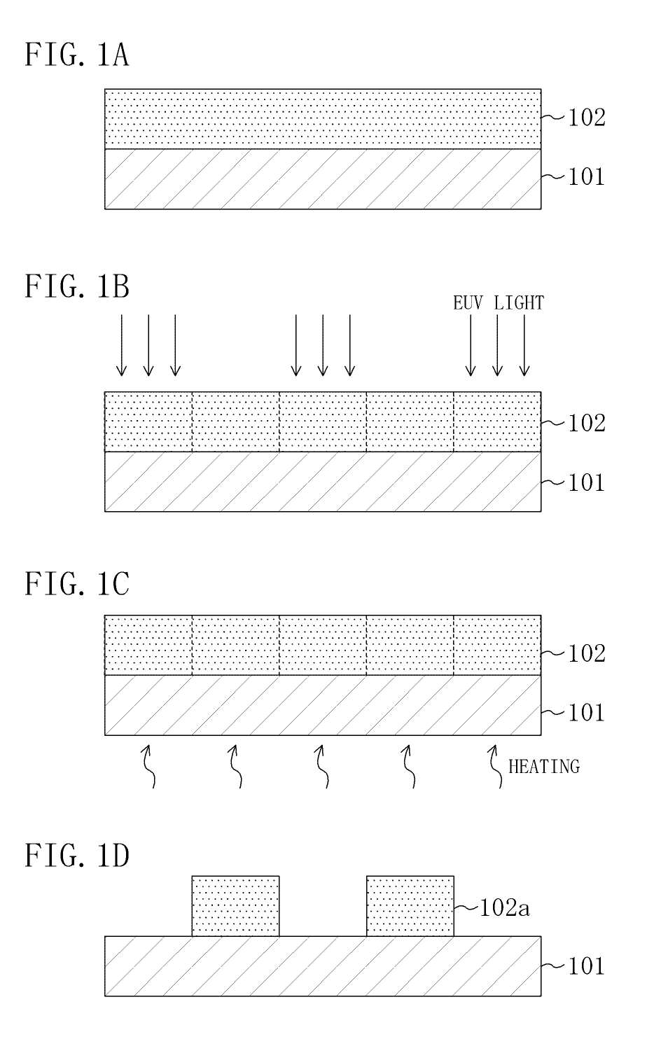

A pattern formation method using a resist material according to a first embodiment of the present disclosure will be described with reference to FIGS. 1A-1D.

First, a positive chemically amplified resist material is prepared, which is molecular resist having the following composition.

α-Cyclodextrin (cyclic oligomer which does not contain any acid-labile group, is soluble in alkali, and is a trimer or a higher multimer): 2 g

t-Butyl methacrylic acid (non-cyclic molecular compound containing an acid-labile group): 0.7 g

Triphenylsulfonium trifluoromethanesulfonate (photoacid generator): 0.05 g

Triethanolamine (quencher): 0.002 g

Propylene glycol monomethyl ether acetate (solvent): 20 g

Next, as shown in FIG. 1A, the resist material is applied onto a substrate 101. Then, a resist film 102 applied with the material is heated at the temperature of 90° C. for 60 seconds, thereby forming the resist film 102 with a thickness of 50 nm.

After that, as shown in FIG. 1B, pattern exposure is performed by irradiating the resist film 102 with exposure light of extreme ultraviolet (EUV) having an NA of 0.25 and a wavelength of 13.5 nm via a mask (not shown).

Since the extreme ultraviolet (EUV) has an extremely short wavelength such as 13.5 nm, a conventional transmissive mask and a conventional refractive optical system are not used as the mask and the optical system, but a reflective mask having extremely high reflectivity of light with a wavelength close to 13.5 nm, and using as a reflecting surface, a multilayer film formed by alternately stacking molybdenum and silicon with thicknesses of several nanometers; and a reflective optical system using as a reflecting surface of a reflective mirror, a multilayer film formed by alternately stacking molybdenum and silicon with thicknesses of several nanometers. Since extreme ultraviolet (EUV) is also absorbed by air, the pattern exposure is performed in a vacuum.

Then, as shown in FIG. 1C, the resist film 102 after the pattern exposure is heated with a hot plate at the temperature of 105° C. for 60 seconds.

Next, the heated resist film 102 is developed with a tetramethylammonium hydroxide developer at a concentration of 2.38 wt %, thereby obtaining, as shown in FIG. 1D, a resist pattern 102a formed of an unexposed portion of the resist film 102 and having a line width of 50 nm.

As such, according to the first embodiment, the molecular resist material contains α-cyclodextrin as the cyclic oligomer which does not contain any acid-labile group, is soluble in alkali, and is a trimer or a higher multimer; and t-butyl methacrylic acid as the non-cyclic molecular compound containing an acid-labile group. Thus, since the α-cyclodextrin prevents reduction in the glass transition temperature, deformation does not occur in the resist film 102 at the time of heating after the pattern exposure. Furthermore, the t-butyl methacrylic acid is sufficiently diffused in the resist film 102, thereby increasing solution blockage of the developer of the α-cyclodextrin in the unexposed portion to improve development contrast. This results in an improvement in the form of the obtained resist pattern 102a, and reduction in roughness of the pattern.

### Second Embodiment

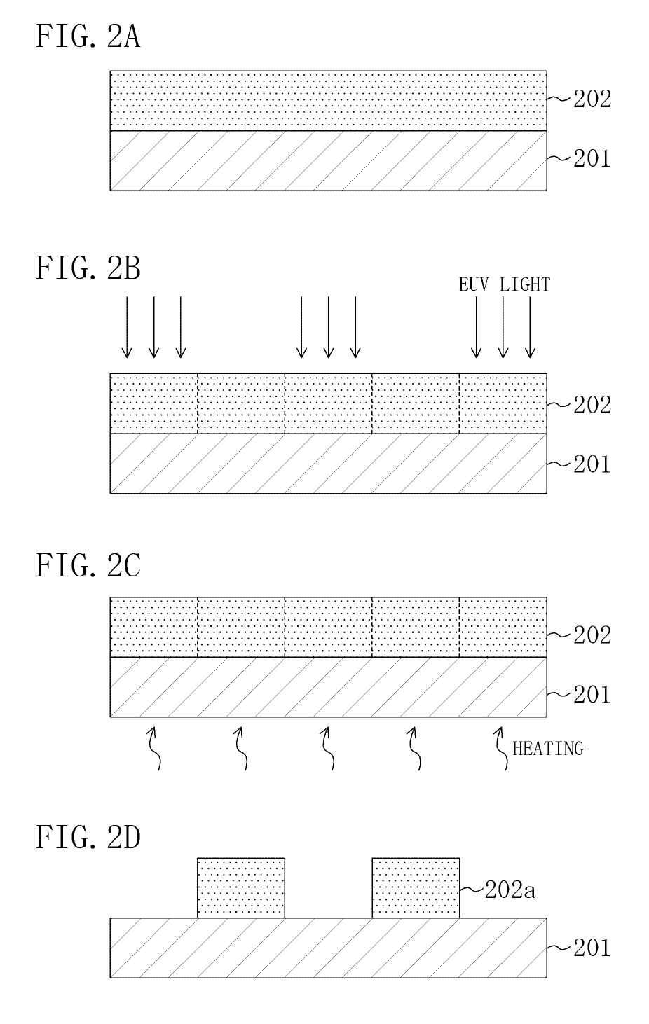

A pattern formation method using a resist material according to a second embodiment of the present disclosure will be described with reference to FIGS. 2A-2D.

First, a positive chemically amplified resist material is prepared, which is molecular resist having the following composition.

Calix[4]arene (cyclic oligomer which does not contain any acid-labile group, is soluble in alkali, and is a trimer or a higher multimer): 2 g

Di(t-butyl)bisphenol A (molecular compound containing an acid-labile group): 0.6 g

Triphenylsulfonium trifluoromethanesulfonate (acid generator): 0.05 g

Triethanolamine (quencher): 0.002 g

Propylene glycol monomethyl ether acetate (solvent): 20 g

Next, as shown in FIG. 2 A, the resist material is applied onto a substrate 201. Then, a resist film 202 applied with the material is heated at the temperature of 90° C. for 60 seconds, thereby forming the resist film 202 with a thickness of 50 nm.

After that, as shown in FIG. 2B, pattern exposure is performed by irradiating the resist film 202 with exposure light of extreme ultraviolet (EUV) having an NA of 0.25 and a wavelength of 13.5 nm via a mask (not shown).

Then, as shown in FIG. 2C, the resist film 202 after the pattern exposure is heated with a hot plate at the temperature of 105° C. for 60 seconds.

Next, the heated resist film 202 is developed with a tetramethylammonium hydroxide developer at a concentration of 2.38 wt %, thereby obtaining, as shown in FIG. 2D, a resist pattern 202a formed of an unexposed portion of the resist film 202 and having a line width of 50 nm.

As such, according to the second embodiment, the molecular resist material contains calix[4]arene as the cyclic oligomer which does not contain any acid-labile group, is soluble in alkali, and is a trimer or a higher multimer; and di(t-butyl)bisphenol A as the molecular compound containing an acid-labile group. Thus, since the calix[4]arene prevents reduction in the glass transition temperature, deformation does not occur in the resist film 202 at the time of heating after the pattern exposure. Furthermore, the di(t-butyl)bisphenol A is sufficiently diffused in the resist film 202, thereby increasing solution blockage of the developer of the calix[4]arene in the unexposed portion to improve development contrast. This results in an improvement in the form of the obtained resist pattern 202a, and reduction in roughness of the pattern.

### Third Embodiment

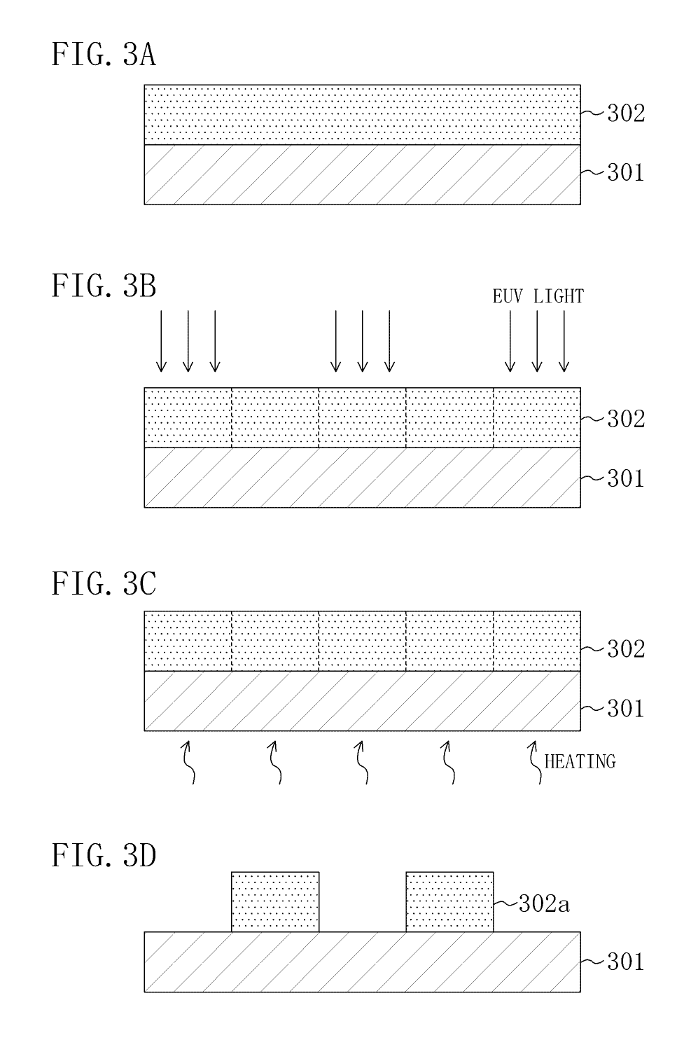

A pattern formation method using a resist material according to a third embodiment of the present disclosure will be described with reference to FIGS. 3A-3D.

First, a positive chemically amplified resist material is prepared, which is molecular resist having the following composition.

β-Cyclodextrin (cyclic oligomer which does not contain any acid-labile group, is soluble in alkali, and is a trimer or a higher multimer): 2 g

2-Methyladamantyl methacrylic acid (molecular compound containing an acid-labile group): 0.5 g

Triphenylsulfonium nonafluorobutane sulfonate (photoacid generator): 0.05 g

Triethanolamine (quencher): 0.002 g

Propylene glycol monomethyl ether acetate (solvent): 20 g

Next, as shown in FIG. 3 A, the resist material is applied onto a substrate 301. Then, a resist film 302 applied with the material is heated at the temperature of 90° C. for 60 seconds, thereby forming the resist film 302 with a thickness of 50 nm.

After that, as shown in FIG. 3B, pattern exposure is performed by irradiating the resist film 302 with exposure light of extreme ultraviolet (EUV) having an NA of 0.25 and a wavelength of 13.5 nm via a mask (not shown).

Then, as shown in FIG. 3C, the resist film 302 after the pattern exposure is heated with a hot plate at the temperature of 115° C. for 60 seconds.

Next, the heated resist film 302 is developed with a tetramethylammonium hydroxide developer at a concentration of 2.38 wt %, thereby obtaining, as shown in FIG. 3D, a resist pattern 302a formed of an unexposed portion of the resist film 302 and having a line width of 50 nm.

As such, according to the third embodiment, the molecular resist material contains the β-cyclodextrin as the cyclic oligomer which does not contain any acid-labile group, is soluble in alkali, and is a trimer or a higher multimer; and the 2-methyladamantyl methacrylic acid as the molecular compound containing an acid-labile group. Thus, since the β-cyclodextrin prevents reduction in the glass transition temperature, deformation does not occur in the resist film 302 at the time of heating after the pattern exposure. Furthermore, the 2-methyladamantyl methacrylic acid is sufficiently diffused in the resist film 302, thereby increasing solution blockage of the developer of the β-cyclodextrin in the unexposed portion to improve development contrast. This results in an improvement in the form of the obtained resist pattern 302a, and reduction in roughness of the pattern.

### Fourth Embodiment

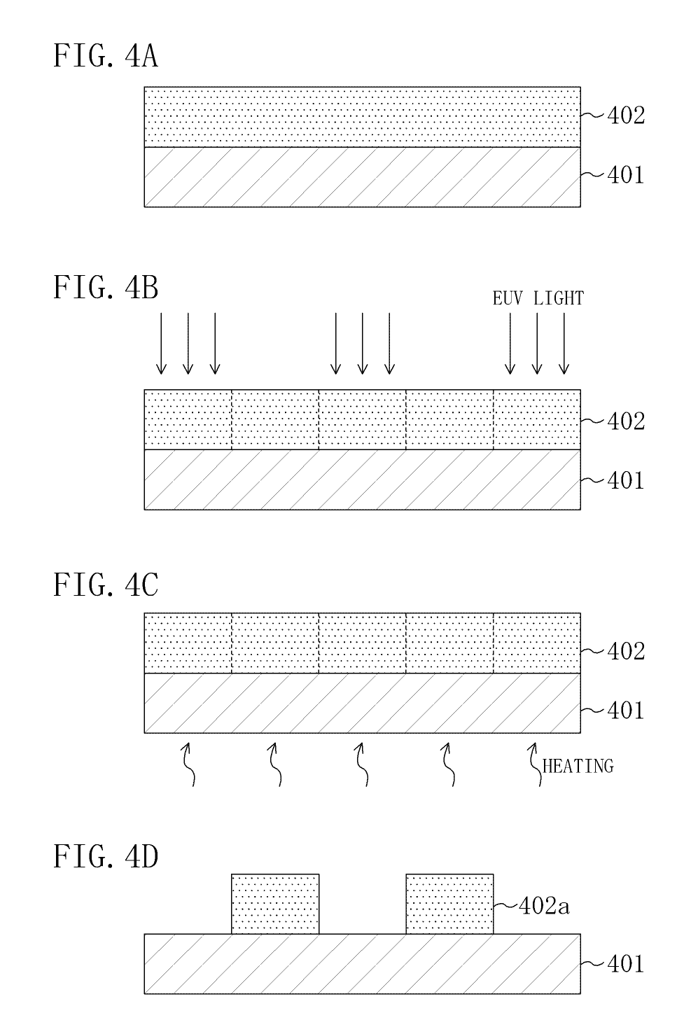

A pattern formation method using a resist material according to a fourth embodiment of the present disclosure will be described with reference to FIGS. 4A-4D.

First, a positive chemically amplified resist material is prepared, which is molecular resist having the following composition.

Resorcinarene (cyclic oligomer which does not contain any acid-labile group, is soluble in alkali, and is a trimer or a higher multimer): 2 g

Di(2-methylcyclopentyl)bisphenol A (molecular compound containing an acid-labile group): 0.5 g

Triphenylsulfonium trifluoromethanesulfonate (photoacid generator): 0.05 g Triethanolamine (quencher): 0.002 g

Propylene glycol monomethyl ether acetate (solvent): 20 g

Next, as shown in FIG. 4 A, the resist material is applied onto a substrate 401. Then, a resist film 402 applied with the material is heated at the temperature of 90° C. for 60 seconds, thereby forming the resist film 402 with a thickness of 50 nm.

After that, as shown in FIG. 4B, pattern exposure is performed by irradiating the resist film 402 with exposure light of extreme ultraviolet (EUV) having an NA of 0.25 and a wavelength of 13.5 nm via a mask (not shown).

Then, as shown in FIG. 4C, the resist film 402 after the pattern exposure is heated with a hot plate at the temperature of 115° C. for 60 seconds.

Next, the heated resist film 402 is developed with a tetramethylammonium hydroxide developer at a concentration of 2.38 wt %, thereby obtaining, as shown in FIG. 4D, a resist pattern 402a formed of an unexposed portion of the resist film 402 and having a line width of 50 nm.

As such, according to the fourth embodiment, the molecular resist material contains resorcinarene as the cyclic oligomer which does not contain any acid-labile group, is soluble in alkali, and is a trimer or a higher multimer; and di(2-methylcyclopentyl)bisphenol A as the molecular compound containing an acid-labile group. Thus, the resorcinarene prevents reduction in the glass transition temperature, deformation does not occur in the resist film 402 at the time of heating after the pattern exposure. Furthermore, the di(2-methylcyclopentyl)bisphenol A is sufficiently diffused in the resist film 402, thereby increasing solution blockage of the developer of the resorcinarene in the unexposed portion to improve development contrast. This results in an improvement in the form of the obtained resist pattern 402a, and reduction in roughness of the pattern.

Note that, in the first to fourth embodiments, the α-cyclodextrin, the β-cyclodextrin, the calix[4]arene, and the resorcinarene are used as the cyclic oligomer which does not contain any acid-labile group, is soluble in alkali, and is a trimer or a higher multimer included in the resist material. The present disclosure is not limited thereto. For example, pyrogallolarene, calixpyrrole, thiocalixarene, homooxacalixarene, or the like may be used as well. The ring sizes are not limited thereto. For example, γ-cyclodextrin, calix[6]arene, calix[8]arene, or the like may be used as well.

The t-butyl methacrylic acid is used as the non-cyclic molecular compound containing an acid-labile group included in the resist material. The present disclosure is not limited thereto. For example, t-butyl acrylic acid, t-butyl-α-fluoroacrylic acid, t-butyloxycarbonyl acrylic acid, t-butyloxycarbonyl methacrylic acid, t-butyloxycarbonyl-α-fluoroacrylic acid, methoxymethyl acrylic acid, methoxymethyl methacrylic acid, methoxymethyl-α-fluoroacrylic acid, or the like may be used as well.

The acid-labile group in the non-cyclic molecular compound containing the acid-labile group may be a 1-ethoxyethyl group, a 2-methyladamantyl group, or a 2-ethyladamantyl group, other than the t-butyl group, the t-butyloxycarbonyl group, and the methoxymethyl group.

The di(t-butyl)bisphenol A, the 2-methyladamantyl methacrylic acid, and the di(2-methylcyclopentyl)bisphenol A are used as the molecular compound containing an acid-labile group included in the resist material. The present disclosure is not limited thereto. For example, t-butylphenol, t-butyl-o-cresol, t-butyl-m-cresol, t-butyl-p-cresol, t-butyl-1-naphthol, t-butyl-2-naphthol, di(t-butyl)catechol, di(t-butyl)resorcinol, tri(t-butyl)pyrogallol, hexa(t-butyl)hexahydroxybenzene, di(t-butyloxycarbonyl)bisphenol A, t-butyloxycarbonylphenol, t-butyloxycarbonyl-o-cresol, t-butyloxycarbonyl-m-cresol, t-butyloxycarbonyl-p-cresol, t-butyloxycarbonyl-1-naphthol, t-butyloxycarbonyl-2-naphthol, di(t-butyloxycarbonyl)catechol, di(t-butyloxycarbonyl)resorcinol, tri(t-butyloxycarbonyl)pyrogallol, hexa(t-butyloxycarbonyl)hexahydroxybenzene, di(1-ethoxyethyl)bisphenol A, 1-ethoxyethyl phenol, (1-ethoxyethyl)o-cresol, (1-ethoxyethyl)m-cresol, (1-ethoxyethyl)p-cresol, (1-ethoxyethyl)1-naphthol, (1-ethoxyethyl)2-naphthol, di(1-ethoxyethyl)catechol, di(1-ethoxyethyl)resorcinol, tri(1-ethoxyethyl)pyrogallol, hexa(1-ethoxyethyl)hexahydroxybenzene, di(methoxymethyl)bisphenol A, methoxymethylphenol, methoxymethyl-o-cresol, methoxymethyl-m-cresol, methoxymethyl-p-cresol, methoxymethyl-1-naphthol, methoxymethyl-2-naphthol, di(methoxymethyl)catechol, di(methoxymethyl)resorcinol, tri(methoxymethyl)pyrogallol, hexa(methoxymethyl)hexahydroxybenzene, 2-methylcyclopentyl acrylic acid, 2-methylcyclopentyl methacrylic acid, 2-methylcyclopentyl-α-fluoroacrylic acid, 2-ethylcyclopentyl acrylic acid, 2-ethylcyclopentyl methacrylic acid, 2-ethylcyclopentyl-α-fluoroacrylic acid, di(2-ethylcyclopentyl)bisphenol A, 2-methyladamantyl acrylic acid, 2-methyladamantyl-α-fluoroacrylic acid, di(2-methyladamantyl)bisphenol A, 2-ethyladamantyl acrylic acid, 2-ethyladamantyl methacrylic acid, 2-ethyladamantyl-α-fluoroacrylic acid, di(2-ethyladamantyl)bisphenol A, or the like may be used as well.

The triphenylsulfonium trifluoromethanesulfonate, and the triphenylsulfonium nonafluorobutane sulfonate are used as the photoacid generator included in the resist material. The present disclosure is not limited thereto. For example, diphenyliodonium trifluoromethanesulfonate, diphenyliodonium nonafluorobutane sulfonate, or the like may be used as well.

The quencher and the solvent included in the resist material are not limited to the materials shown in the first to third embodiments, and any material having the equivalent characteristics may be used.

The extreme ultraviolet (EUV) is used as the exposure light source in the pattern exposure. The present disclosure is not limited thereto. For example, ArF excimer laser light or an electron beam may be used as well.

The resist material and the pattern formation method using the resist material of the present disclosure provide high thermal stability and high development contrast to reduce deformation of fine patterns, and are thus useful as a resist material and a pattern formation method using the resist material etc. used in a manufacturing process etc. of a semiconductor device.

What is claimed is:

1. A resist material comprising:
cyclic oligomer which does not contain any acid-labile group, is soluble in alkali, and is a trimer or a higher multimer;
a molecular compound containing an acid-labile group;
a photoacid generator; and
no polymer.

2. The resist material of claim 1, wherein
the cyclic oligomer is cyclodextrin, calixarene, resorcinarene, pyrogallolarene, calixpyrrole, thiocalixarene, or homooxacalixarene.

3. The resist material of claim 2, wherein
the cyclodextrin is α-cyclodextrin, β-cyclodextrin, or γ-cyclodextrin.

4. The resist material of claim 2, wherein
the calixarene is calix[4]arene, calix[6]arene, or calix[8]arene.

5. The resist material of claim 1, wherein
the molecular compound containing an acid-labile group is a non-cyclic molecular compound.

6. The resist material of claim 5, wherein
the acid-labile group in the non-cyclic molecular compound is a t-butyl group, a t-butyloxycarbonyl group, a 1-ethoxyethyl group, a methoxymethyl group, a 2-methyladamantyl group, or a 2-ethyladamantyl group.

7. The resist material of claim 5, wherein
the non-cyclic molecular compound containing an acid-labile group is t-butyl acrylic acid, t-butyl methacrylic acid, t-butyl-α-fluoroacrylic acid, t-butyloxycarbonyl acrylic acid, t-butyloxycarbonyl methacrylic acid, t-butyloxycarbonyl-α-fluoroacrylic acid, methoxymethyl acrylic acid, methoxymethyl methacrylic acid, or methoxymethyl-α-fluoroacrylic acid.

8. The resist material of claim 1, wherein
the molecular compound containing an acid-labile group is di(t-butyl)bisphenol A, t-butylphenol, t-butyl-o-cresol, t-butyl-m-cresol, t-butyl-p-cresol, t-butyl-1-naphthol, t-butyl-2-naphthol, di(t-butyl)catechol, di(t-butyl)resorcinol, tri(t-butyl)pyrogallol, hexa(t-butyl)hexahydroxybenzene, di(t-butyloxycarbonyl)bisphenol A, t-butyloxycarbonylphenol, t-butyloxycarbonyl-o-cresol, t-butyloxycarbonyl-m-cresol, t-butyloxycarbonyl-p-cresol, t-butyloxycarbonyl-1-naphthol, t-butyloxycarbonyl-2-naphthol, di(t-butyloxycarbonyl)catechol, di(t-butyloxycarbonyl)resorcinol, tri(t-butyloxycarbonyl)pyrogallol, hexa(t-butyloxycarbonyl)hexahydroxybenzene, di(1-ethoxyethyl)bisphenol A, 1-ethoxyethyl phenol, (1-ethoxyethyl)o-cresol, (1-ethoxyethyl)m-cresol, (1-ethoxyethyl)p-cresol, (1-ethoxyethyl)1-naphthol, (1-ethoxyethyl)2-naphthol, di(1-ethoxyethyl)catechol, di(1-ethoxyethyl)resorcinol, tri(1-ethoxyethyl)pyrogallol, hexa(1-ethoxyethyl)hexahydroxybenzene, di(methoxymethyl)bisphenol A, methoxymethylphenol, methoxymethyl-o-cresol, methoxymethyl-m-cresol, methoxymethyl-p-cresol, methoxymethyl-1-naphthol, methoxymethyl-2-naphthol, di(methoxymethyl)catechol, di(methoxymethyl)resorcinol, tri(methoxymethyl)pyrogallol, hexa(methoxymethyl)hexahydroxybenzene, 2-methylcyclopentyl acrylic acid, 2-methylcyclopentyl methacrylic acid, 2-methylcyclopentyl-α-fluoroacrylic acid, di(2-methylcyclopentyl)bisphenol A, 2-ethylcyclopentyl acrylic acid, 2-ethylcyclopentyl methacrylic acid, 2-ethylcyclopentyl-α-fluoroacrylic acid, di(2-ethylcyclopentyl)bisphenol A, 2-methyladamantyl acrylic acid, 2-methyladamantyl methacrylic acid, 2-methyladamantyl-α-fluoroacrylic acid, di(2-methyladamantyl)bisphenol A, 2-ethyladamantyl acrylic acid, 2-ethyladamantyl methacrylic acid, 2-ethyladamantyl-α-fluoroacrylic acid, or di(2-ethyladamantyl)bisphenol A.

9. The resist material of claim 1, wherein
the photoacid generator is triphenylsulfonium trifluoromethanesulfonate, triphenylsulfonium nonafluorobutane sulfonate, diphenyliodonium trifluoromethanesulfonate, or diphenyliodonium nonafluorobutane sulfonate.

10. A pattern formation method comprising:
forming on a substrate, a resist film from a resist material including cyclic oligomer which does not contain any acid-labile group, is soluble in alkali, and is a trimer or a higher multimer, a molecular compound containing an acid-labile group, a photoacid generator, and no polymer,
performing pattern exposure by selectively irradiating the resist film with exposure light;
heating the resist film after the pattern exposure; and
developing the heated resist film to form a resist pattern from the resist film.

11. The pattern formation method of claim 10, wherein
the cyclic oligomer is cyclodextrin, calixarene, resorcinarene, pyrogallolarene, calixpyrrole, thiocalixarene, or homooxacalixarene.

12. The pattern formation method of claim 11, wherein
the cyclodextrin is α-cyclodextrin, β-cyclodextrin, or γ-cyclodextrin.

13. The pattern formation method of claim 11, wherein
the calixarene is calix[4]arene, calix[6]arene, or calix[8]arene.

14. The pattern formation method of claim 10, wherein
the molecular compound containing an acid-labile group is a non-cyclic molecular compound.

15. The pattern formation method of claim 14, wherein
the acid-labile group in the non-cyclic molecular compound is a t-butyl group, a t-butyloxycarbonyl group, a 1-ethoxyethyl group, a methoxymethyl group, a 2-methyladamantyl group, or a 2-ethyladamantyl group.

16. The pattern formation method of claim 14, wherein
the non-cyclic molecular compound containing an acid-labile group is t-butyl acrylic acid, t-butyl methacrylic acid, t-butyl-α-fluoroacrylic acid, t-butyloxycarbonyl acrylic acid, t-butyloxycarbonyl methacrylic acid, t-butyloxycarbonyl-α-fluoroacrylic acid, methoxymethyl acrylic acid, methoxymethyl methacrylic acid, or methoxymethyl-α-fluoroacrylic acid.

17. The pattern formation method of claim 10, wherein
the molecular compound containing an acid-labile group is di(t-butyl)bisphenol A, t-butylphenol, t-butyl-o-cresol, t-butyl-m-cresol, t-butyl-p-cresol, t-butyl-1-naphthol, t-butyl-2-naphthol, di(t-butyl)catechol, di(t-butyl)resorcinol, tri(t-butyl)pyrogallol, hexa(t-butyl)hexahydroxybenzene, di(t-butyloxycarbonyl)bisphenol A, t-butyloxycarbonylphenol, t-butyloxycarbonyl-o-cresol, t-butyloxycarbonyl-m-cresol, t-butyloxycarbonyl-p-cresol, t-butyloxycarbonyl-1-naphthol, t-butyloxycarbonyl-2-naphthol, di(t-butyloxycarbonyl)catechol, di(t-butyloxycarbonyl)resorcinol, tri(t-butyloxycarbonyl)pyrogallol, hexa(t-butyloxycarbonyl)hexahydroxybenzene, di(1-ethoxyethyl)bisphenol A, 1-ethoxyethyl phenol, (1-ethoxyethyl)o-cresol, (1-ethoxyethyl)m-cresol, (1-ethoxyethyl)p-cresol, (1-ethoxyethyl)1-naphthol, (1-ethoxyethyl)2-naphthol, di(1-ethoxyethyl)catechol, di(1-ethoxyethyl)resorcinol, tri(1-ethoxyethyl)pyrogallol, hexa(1-ethoxyethyl)hexahydroxybenzene, di(methoxymethyl)bisphenol A, methoxymethylphenol, methoxymethyl-o-cresol, methoxymethyl-m-cresol, methoxymethyl-p-cresol, methoxymethyl-1-naphthol, methoxymethyl-2-naphthol, di(methoxymethyl)catechol, di(methoxymethyl)resorcinol, tri(methoxymethyl)pyrogallol, hexa(methoxymethyl)hexahydroxybenzene, 2-methylcyclopentyl acrylic acid, 2-methylcyclopentyl methacrylic acid, 2-methylcyclopentyl-α-fluoroacrylic acid, di(2-methylcyclopentyl)bisphenol A, 2-ethylcyclopentyl acrylic acid, 2-ethylcyclopentyl methacrylic acid, 2-ethylcyclopentyl-α-fluoroacrylic acid, di(2-ethylcyclopentyl)bisphenol A, 2-methyladamantyl acrylic acid, 2-methyladamantyl methacrylic acid, 2-methyladamantyl-α-fluoroacrylic acid, di(2-methyladamantyl)bisphenol A, 2-ethyladamantyl acrylic acid, 2-ethyladamantyl methacrylic acid, 2-ethyladamantyl-α-fluoroacrylic acid, or di(2-ethyladamantyl)bisphenol A.

18. The pattern formation method of claim 10, wherein
the photoacid generator is triphenylsulfonium trifluoromethanesulfonate, triphenylsulfonium nonafluorobutane sulfonate, diphenyliodonium trifluoromethanesulfonate, or diphenyliodonium nonafluorobutane sulfonate.

19. The pattern formation method of claim 10, wherein
the exposure light is ArF excimer laser light, extreme ultraviolet, or an electron beam.
